(19) United States
(12) Patent Application Publication
(10) Pub. No.: US 2017/0369747 A1
(43) Pub. Date: Dec. 28, 2017

(54) RESIN COMPOSITION, ADHESIVE FILM, AND CIRCUIT BOARD USING THE SAME

(71) Applicant: Zhen Ding Technology Co., Ltd., Tayuan (TW)

(72) Inventors: SZU-HSIANG SU, New Taipei (TW); KUO-SHENG LIANG, New Taipei (TW); SHOU-JUI HSIANG, New Taipei (TW); HONG-PING LIN, New Taipei (TW)

(21) Appl. No.: 15/231,723

(22) Filed: Aug. 8, 2016

(30) Foreign Application Priority Data
Jun. 24, 2016 (TW) 105119940

(51) Int. Cl. C09J 109/06; B32B 27/30; B32B 27/18; C09J 1/00; C09J 7/02; H05K 1/03; C08L 9/06

(52) U.S. Cl. CPC C09J 109/06; H05K 1/0373; B32B 27/302; C08L 9/06; C09J 1/00; C09J 7/026; B32B 27/18; C08L 2203/206; C08L 2203/162; C08L 2201/02; B32B 2405/00; H05K 2201/0116; C09J 2203/326; C09J 2205/114; B32B 2264/102; B32B 2457/08

(57) ABSTRACT

A resin composition for a PCB includes a styrene-butadiene-styrene block copolymer in an amount from 95 to 100 parts by weight, a modified porous spheres of silicon oxide in an amount from 1 to 50 parts by weight, and a liquid polybutadiene in an amount from 5 to 50 parts by weight. The styrene-butadiene-styrene block copolymer and the liquid polybutadiene both include vinyl groups on the molecular side chains. The modified porous spheres of silicon oxide also include vinyl groups. An adhesive film and a circuit board using the resin composition are also provided.

### FIELD

The subject matter generally relates to a resin composition, an adhesive film using the resin composition, and a circuit board using the resin composition.

### BACKGROUND

Circuit boards generally include conductive circuits and insulating layers coupling the conductive circuits. A high dielectric constant of the insulating layer may affect impedance matching of the circuit board and thus slow down a high frequency signal transmission in the circuit board. Thus, an insulating layer having a low dielectric constant is needed.

### BRIEF DESCRIPTION OF THE DRAWINGS

Implementations of the present technology will now be described, by way of example only, with reference to the attached figures.

FIG. 1 is a cross-sectional view of an exemplary embodiment of an adhesive film.

FIG. 2 is a cross-sectional view of a circuit board using the adhesive film of FIG. 1.

FIG. 3 is a cross-sectional view of a test sample of the circuit board of FIG. 2.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “comprising” when utilized, means “including, but not necessarily limited to”; it specifically indicates open-ended inclusion or membership in the so-described combination, group, series, and the like. The term “about” when utilized, means “not only include the numerical value, but also includes numbers close to the numerical value.”

An exemplary embodiment of a resin composition comprises a styrene-butadiene-styrene block copolymer (SBS) in an amount of about 95 to about 100 parts by weight, modified porous spheres of silicon oxide in an amount of about 1 to about 50 parts by weight, and a liquid polybutadiene in an amount of about 5 to about 50 parts by weight.

The SBS comprises vinyl groups on its side chains. The SBS can be selected from a group consisting of an SBS obtainable from Kraton Polymers under the trade names “D1101”, “DX405”, or any combination thereof.

The modified porous spheres of silicon oxide are formed by processing silicon oxide to form nanoporous material and modifying the porous silicon oxide to form vinyl groups.

The liquid polybutadiene comprises vinyl groups on its side chains. The vinyl groups of the liquid polybutadiene are able to react with the vinyl groups of the SBS and the modified porous spheres of silicon oxide when the resin composition is heated, thereby forming a cross-linking network structure. The cross-linking structure has a higher density than a resin composition in the absence of the modified porous spheres of silicon oxide. In addition, the cross-linking network structure can prevent the modified porous spheres of silicon oxide from being agglomerated in the resin composition, thus allowing the modified porous spheres of silicon oxide to be uniformly dispersed in the resin composition. Such resin composition is also easily stored.

The liquid polybutadiene may be selected from a group consisting of liquid polybutadiene having vinyl groups in an amount greater than or equal to 50% by weight, and liquid maleic polybutadiene, or any combination thereof.

The liquid polybutadiene having vinyl groups in an amount greater than or equal to 50% by weight may be selected from a group consisting of liquid polybutadiene obtainable from Cray Valley Corporation under the trade names “Ricon 142”, “Ricon 150”, “Ricon 152”, “Ricon 153”, “Ricon 154”, “Ricon 156”, “Ricon 157”, or any combination thereof.

The liquid maleic polybutadiene may be selected from a group consisting of maleic polybutadiene obtainable from Cray Valley Corporation under the trade names “Ricon 130MA8”, “Ricon 130MA13”, “Ricon 130MA20”, “Ricon 142MA3”, “Ricon 184MA6”, “Ricobond 1731”, “Ricobond 2031”, “Ricobond 1756”, or any combination thereof.

The resin composition further comprises an additive selected from a group consisting of a flame retardant, an ion trapper, or any combination thereof. If the resin composition comprises the flame retardant, the flame retardant is in an amount of about 5 to about 250 parts by weight. If the resin composition comprises the ion trapper, the ion trapper is in an amount of about 0.5 to about 10 parts by weight.

The flame retardant may be phosphate compound. In at least one exemplary embodiment, the flame retardant may be selected from a group consisting of bisphenol diphenyl phosphate, ammonium polyphosphate, hydroquinone bis-(diphenyl phosphate), trimethyl phosphate (TMP), dimethyl methyl phosphonate (DMMP), resoreinol dixylenylphosphate (RDXP), melamine polyphosphate, accidentally phosphorus compounds, phosphazene compound, 9,10-dihydro-9-oxa-10-phosphaphenanthrene-10-oxide (DOPO), or any combination thereof.

The ion trapper may be selected from a group consisting of aluminum silicate, hydrated metal oxide, polyvalent metal salt, heteropoly acid, or any combination thereof. The hydrated metal oxide may be selected from a group consisting of antimony oxide hydrate (Sb₂O₅.2H₂O), and bismuth oxide hydrate (Bi₂O₃.nH₂O), such as an ion trapper obtainable from TOAGOSEI CO., LTD under the trade names“IEX-600”. The polyvalent metal salt may be selected from a group consisting of zirconium hydrogen phosphate monohydrate (Zr(HPO₄)₂.H₂O), titanium hydrogen phosphate monohydrate (Ti(HPO₄)₂.H₂O), or any combination thereof. The heteropoly acid may be selected from a group consisting of molybdenum ammonia phosphate hydrate ((NH₄)₃Mo₁₂(PO₄)₄₀.nH₂O), hydroxyapatite (Ca₁₀(PO₄)₆(OH)₂), aluminum magnesium carbonate hydroxide hydrate (AlMg(OH)₃ CO₃.nH₂O), or any combination thereof.

An exemplary embodiment of a method for preparing the resin composition may comprise the following steps.

Step 1, the SBS in an amount of about 95 to about 100 parts by weight, the modified porous spheres of silicon oxide in an amount of about 1 to about 50 parts by weight, the liquid polybutadiene in an amount of about 5 to about 50 parts by weight, and the additive in an amount of about 0.5 to about 260 parts by weight, are all added into a container to obtain a mixture.

Step 2, the mixture is stirred to cause the SBS, the modified porous spheres of silicon oxide, the liquid polybutadiene, and the additive to be fully mixed.

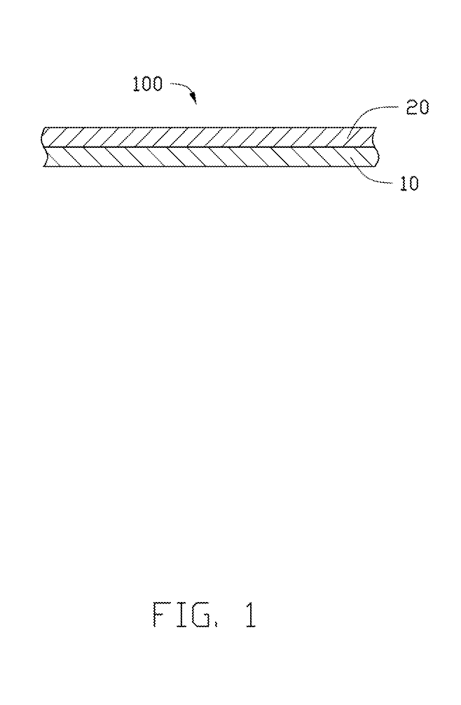

FIG. 1 illustrates an embodiment of an adhesive film 100 made by the resin composition. The adhesive film 100 comprises a release film 10 and a resin layer 20 attached to at least one surface of the release film 10. The adhesive film 100 may be made by coating the resin composition on the at least one surface of the release film 10 and then solidifying the resin composition to form the resin layer 20. In at least one embodiment, the coated resin composition is solidified for 15 mins at 110 degrees centigrade to form the adhesive film 100. The resin layer 20 is a semi-solidified layer.

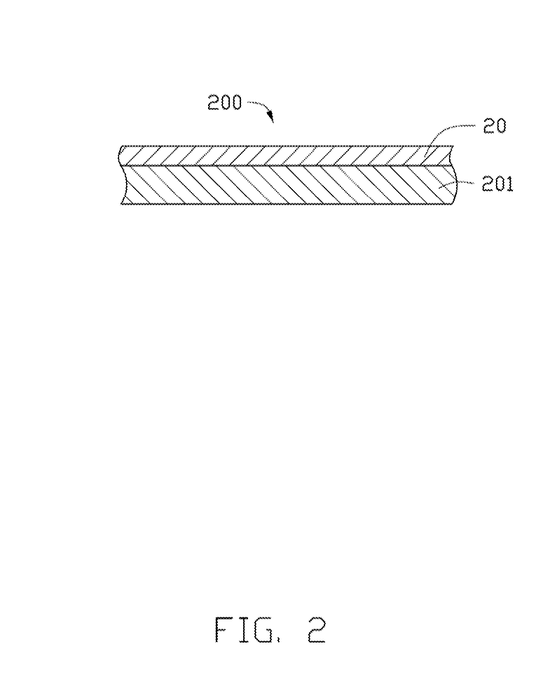

FIG. 2 illustrates an embodiment of a circuit board 200 made by the resin layer 20. The circuit board 200 comprises a circuit substrate 201 and the resin layer 20 attached on at least one surface of the circuit substrate 201. The resin layer 20 may be attached to the circuit substrate 201 by hot-pressing.

When the resin composition is heated, the vinyl groups of the SBS, the modified porous spheres of silicon oxide, and the liquid polybutadiene will react with each other to form a cross-linking network structure. The cross-linking density of the resin composition is thus improved. The resin layer 20 has a better heat resistance to avoid destruction when being soldered. In addition, the cross-linking network structure causes the modified porous spheres of silicon oxide to be uniformly dispersed in the resin layer 20. This prevents any decrease in the adhesive strength of the resin layer 20 and causes roughness of the surfaces of the resin layer 20. When the resin layer 20 made by the resin composition and the circuit substrate 201 are pressed together, the modified porous spheres of silicon oxide being uniformly dispersed in the resin composition ensures that the adhesion strength of the resin layer 20 is uniform.

### Example 1

The resin composition was made by adding SBS (Manufacturer: Kraton Polymers, Model: D1101) of 100 g, liquid maleic polybutadiene (Manufacturer: Cray Valley Corporation, Model: Ricon 184MA6) of 10 g, modified porous spheres of silicon oxide of 3.5 g, and ion trapper (Manufacturer: TOAGOSEI CO., LTD., Model: IEX-600) of 5 g into a container and stirring until the SBS, the liquid maleic polybutadiene, the modified porous spheres of silicon oxide, and the ion trapper were fully mixed.

### Example 2

The resin composition was made by adding an amount of SBS (Manufacturer: Kraton Polymers, Model: DX405) of 95 g, liquid polybutadiene (Manufacturer: Cray Valley Corporation, Model: Ricon 150) of 10 g, modified porous spheres of silicon oxide of 3.5 g, and ion trapper (Manufacturer: TOAGOSEI CO., LTD., Model: IEX-600) of 5 g into a container and stirring until the SBS, the liquid polybutadiene, the modified porous spheres of silicon oxide, and the ion trapper were fully mixed.

### Comparative Example 1

A composition was made by adding an amount of SBS (Manufacturer: Kraton Polymers, Model: D1101) of 100 g, liquid maleic polybutadiene (Manufacturer: Cray Valley Corporation, Model: Ricon 184MA6) of 10 g, and ion trapper (Manufacturer: TOAGOSEI CO., LTD., Model: IEX-600) of 5 g into a container and stirring until the SBS, the liquid maleic polybutadiene, and the ion trapper were fully mixed.

### Comparative Example 2

A composition was made by adding an amount of SBS (Manufacturer: Kraton Polymers, Model: DX405) of 95 g, liquid polybutadiene (Manufacturer: Cray Valley Corporation, Model: Ricon 150) of 10 g, and ion trapper (Manufacturer: TOAGOSEI CO., LTD., Model: IEX-600) of 5 g into a container and stirring until the SBS, the liquid polybutadiene, and the ion trapper were fully mixed.

### Comparative Example 3

A composition was made by adding an amount of SBS (Manufacturer: Kraton Polymers, Model: D1101) of 100 g, liquid maleic polybutadiene (Manufacturer: Cray Valley Corporation, Model: Ricon 184MA6) of 10 g, unmodified porous spheres of silicon oxide of 3.5 g, and ion trapper (Manufacturer: TOAGOSEI CO., LTD., Model: IEX-600) of 5 g into a container and stirring until the SBS, the liquid maleic polybutadiene, the unmodified porous spheres of silicon oxide, and the ion trapper were fully mixed.

### Comparative Example 4

A composition was made by adding an amount of SBS (Manufacturer: Kraton Polymers, Model: DX405) of 95 g, liquid polybutadiene (Manufacturer: Cray Valley Corporation, Model: Ricon 150) of 10 g, unmodified porous spheres of silicon oxide of 3.5 g, and ion trapper (Manufacturer: TOAGOSEI CO., LTD., Model: IEX-600) of 5 g into a container and stirring until the SBS, the liquid polybutadiene, the unmodified porous spheres of silicon oxide, and the ion trapper were fully mixed.

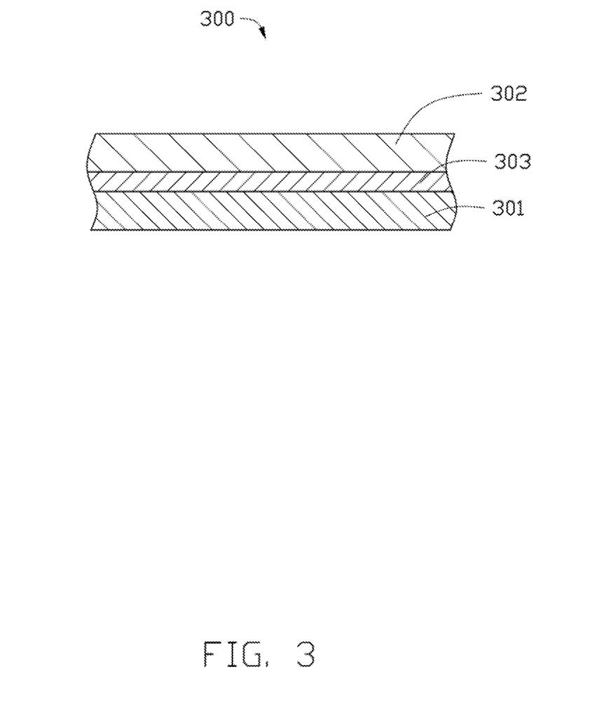

FIG. 3 illustrates a test sample 300 made by the resin composition of the example 1. The test sample 300 comprises a copper foil 301, a polyimide (PI) film 302, and a resin film 303 sandwiched between the copper foil 301 and the polyimide film 302. The resin film 303 was attached to the copper foil 301 and the polyimide film 302. In the illustrated embodiment, the resin film 303 used for making the test sample 300 was made by the resin composition of the example 1.

Furthermore, five other test samples 300 were made by the above-described method using the resin compositions of the examples 2 and compositions of the comparative examples 1, 2, 3, and 4, respectively.

The dielectric constant and the dielectric dissipation factor of each of the resin films formed by the resin compositions made in examples 1 to 2 and the compositions made in the comparative examples 1 to 4 were tested.

Copper peeling strength, PI peeling strength, dispersing property of the modified porous spheres of silicon oxide, and film forming property of the resin film of the six test samples 300 were tested, and the test results were shown in Table 1. If the resin film has no precipitant at a bottom surface, the dispersing property of the modified porous spheres of silicon oxide is “good”; otherwise the dispersing property is “bad”. If the surfaces of the resin film are flat, the film forming property of the resin film is “good”; otherwise the film forming property is “bad”.

TABLE 1

| | Products | | | | | |
|---|---|---|---|---|---|---|
| | | | Compar- | Compar- | Compar- | Compar- |
| | | | ative | ative | ative | ative |
| | Example | Example | example | example | example | example |
| Property | 1 | 2 | 1 | 2 | 3 | 4 |
| Dielectric constant | 2.57 | 2.45 | 2.70 | 2.56 | 2.57 | 2.46 |
| (10 GHz) | | | | | | |
| Dielectric dissipation | 0.006 | 0.007 | 0.006 | 0.007 | 0.006 | 0.007 |
| factor (10 GHz) | | | | | | |
| Copper peeling | 0.98 | 1.21 | 1.10 | 1.35 | 0.59 | 0.61 |
| strength (kgf/cm) | | | | | | |
| PI peeling strength | 1.01 | 1.13 | 1.17 | 1.27 | 0.48 | 0.42 |
| (kgf/cm) | | | | | | |
| Dispersing property of | good | good | — | — | bad | bad |
| the modified porous | | | | | | |
| spheres of silicon oxide | | | | | | |
| Film forming property | good | good | good | good | bad | bad |
| of the resin film | | | | | | |

According to Table 1, the dielectric constant of the resin films made by the resin compositions of example 1 is lower than those of the resin films made by the compositions of comparative example 1, and the dielectric constant of the resin films made by the resin compositions of the example 2 is lower than those of the resin films made by the compositions of comparative example 2. In addition, the copper peeling strength and the PI peeling strength of the resin films made by the resin compositions of examples 1 and 2 are higher than those of the resin films made by the compositions of comparative examples 3 and 4. The dispersing property of the modified porous spheres of silicon oxide and the film forming property of the resin film made by the resin compositions of examples 1 and 2 are better than those of the resin films made by the compositions of comparative examples 3 and 4.

The embodiments shown and described above are only examples. Even though numerous characteristics and advantages of the present technology have been set forth in the foregoing description, together with details of the structures and function of the present disclosure, the disclosure is illustrative only, and changes can be made in the detail, including in matters of shape, size, and arrangement of the parts within the principles of the present disclosure, up to and including, the full extent established by the broad general meaning of the terms used in the claims.

What is claimed is:

1. A resin composition comprising:
a styrene-butadiene-styrene block copolymer in an amount from 95 to 100 parts by weight, the styrene-butadiene-styrene block copolymer comprising vinyl groups at side chains;
modified porous spheres of silicon oxide in an amount from 1 to 50 parts by weight, the modified porous spheres of silicon oxide comprising vinyl groups; and
a liquid polybutadiene in an amount from 5 to 50 parts by weight, the liquid polybutadiene comprising vinyl groups on its side chains.

2. The resin composition of claim 1, wherein the modified porous spheres of silicon oxide comprise nano pores.

3. The resin composition of claim 1, wherein the liquid polybutadiene is selected from a group consisting of liquid polybutadiene having vinyl groups in an amount greater than or equal to 50% by weight, and liquid maleic polybutadiene, or any combination thereof.

4. The resin composition of claim 1, wherein the resin composition further comprises a flame retardant in a range from 5 to 250 parts by weight.

5. The resin composition of claim 4, wherein the flame retardant is selected from a group consisting of bisphenol diphenyl phosphate, ammonium polyphosphate, hydroquinone bis-(diphenyl phosphate), trimethyl phosphate, dimethyl methyl phosphonate, resoreinol dixylenylphosphate, melamine polyphosphate, accidentally phosphorus compounds, phosphazene compound, 9,10-dihydro-9-oxa-10-phosphaphenanthrene-10-oxide, or any combination thereof.

6. The resin composition of claim 1, wherein the resin composition further comprises an ion trapper in a range from 0.5 to 10 parts by weight.

7. The resin composition of claim 6, wherein the ion trapper is selected from a group consisting of aluminum silicate, hydrated metal oxide, polyvalent metal salt, heteropoly acid, or any combination thereof.

8. An adhesive film comprising:
a release film; and
a resin layer attached to at least one surface of the release film, the resin layer comprising:
a styrene-butadiene-styrene block copolymer in an amount from 95 to 100 parts by weight, the styrene-butadiene-styrene block copolymer comprising vinyl groups on its side chains;
a modified porous spheres of silicon oxide in an amount from 1 to 50 parts by weight, the modified porous spheres of silicon oxide comprising vinyl groups; and
a liquid polybutadiene in an amount from 5 to 50 parts by weight, the liquid polybutadiene comprising vinyl groups on its side chains;
wherein the vinyl groups of the styrene-butadiene-styrene block copolymer react with the vinyl groups of the liquid polybutadiene and the modified porous spheres of silicon oxide to obtain a chemical cross-linking network structure, when the resin layer is heated.

9. The adhesive film of claim 8, wherein the modified porous spheres of silicon oxide comprise nano pores.

10. The adhesive film of claim 8, wherein the liquid polybutadiene is selected from a group consisting of liquid polybutadiene having vinyl groups in an amount greater than or equal to 50% by weight, and liquid maleic polybutadiene, or any combination thereof.

11. The adhesive film of claim 8, wherein the resin composition further comprises a flame retardant in a range from 5 to 250 parts by weight.

12. The adhesive film of claim 11, wherein the flame retardant is selected from a group consisting of bisphenol diphenyl phosphate, ammonium polyphosphate, hydroquinone bis-(diphenyl phosphate), trimethyl phosphate, dimethyl methyl phosphonate, resoreinol dixylenylphosphate, melamine polyphosphate, accidentally phosphorus compounds, phosphazene compound, 9,10-dihydro-9-oxa-10-phosphaphenanthrene-10-oxide, or any combination thereof.

13. The adhesive film of claim 8, wherein the resin composition further comprises an ion trapper in a range from 0.5 to 10 parts by weight.

14. The adhesive film of claim 13, wherein the ion trapper is selected from a group consisting of aluminum silicate, hydrated metal oxide, polyvalent metal salt, heteropoly acid, or any combination thereof.

15. A circuit board comprising:
at least one circuit substrate; and
a resin layer attached to at least one surface of the circuit substrate via hot-pressing, the resin layer comprising:
a styrene-butadiene-styrene block copolymer in an amount from 95 to 100 parts by weight, the styrene-butadiene-styrene block copolymer comprising vinyl groups on its side chains;
a modified porous spheres of silicon oxide in an amount from 1 to 50 parts by weight, the modified porous spheres of silicon oxide comprising vinyl groups; and
a liquid polybutadiene in an amount from 5 to 50 parts by weight, the liquid polybutadiene comprising vinyl groups on its side chains;
wherein the vinyl groups of the styrene-butadiene-styrene block copolymer react with the vinyl groups of the liquid polybutadiene and the modified porous spheres of silicon oxide to obtain a chemical cross-linking network structure, when the resin layer is heated.

16. The circuit board of claim 15, wherein the modified porous spheres of silicon oxide comprise nano pores.

17. The circuit board of claim 15, wherein the liquid polybutadiene is selected from a group consisting of liquid polybutadiene having vinyl groups in an amount greater than or equal to 50% by weight, and liquid maleic polybutadiene, or any combination thereof.

18. The circuit board of claim 15, wherein the resin composition further comprises a flame retardant in a range from 5 to 250 parts by weight and/or an ion trapper in a range from 0.5 to 10 parts by weight.

19. The circuit board of claim 18, wherein the flame retardant is selected from a group consisting of bisphenol diphenyl phosphate, ammonium polyphosphate, hydroquinone bis-(diphenyl phosphate), trimethyl phosphate, dimethyl methyl phosphonate, resoreinol dixylenylphosphate, melamine polyphosphate, accidentally phosphorus compounds, phosphazene compound, 9,10-dihydro-9-oxa-10-phosphaphenanthrene-10-oxide, or any combination thereof.

20. The circuit board of claim 18, wherein the ion trapper is selected from a group consisting of aluminum silicate, hydrated metal oxide, polyvalent metal salt, heteropoly acid, or any combination thereof.
